(19) United States
(12) Patent Application Publication
(10) Pub. No.: US 2016/0071936 A1
(43) Pub. Date: Mar. 10, 2016

(54) METHOD FOR PRODUCING A SCHOTTKY DIODE ON A DIAMOND SUBSTRATE

(71) Applicants: CENTRE NATIONAL DE LA RECHERCHE SCIENTIFIQUE, Paris Cedex 16 (FR); UNIVERSITE JOSEPH FOURIER, Grenoble Cedex 9 (FR); INSTITUT POLYTECHNIQUE DE GRENOBLE, Grenoble (FR)

(72) Inventors: David Eon, Saint Martin D'heres (FR); Etienne Gheeraert, Sassenage (FR); Pierre Muret, Saint Martin D'uriage (FR); Julien Pernot, Saint Martin D'heres (FR); Aboulaye Traore, Grenoble (FR)

(73) Assignees: Centre National de la Recherche Scientifique, Paris Cedex 16 (FR); Universite Joseph Fourier, Grenoble Cedex 9 (FR); Institut Polytechnique de Grenoble, Grenoble Cedex 1 (FR)

(21) Appl. No.: 14/786,130

(22) PCT Filed: Apr. 18, 2014
(86) PCT No.: PCT/FR2014/050952

§ 371 Date: Oct. 21, 2015

(30) Foreign Application Priority Data
Apr. 22, 2013 (FR) 1353647

(51) Int. Cl. H01L 29/16; H01L 21/285; H01L 29/45; H01L 21/324; H01L 29/47; H01L 29/66; H01L 21/268

(52) U.S. Cl. CPC H01L 29/1602; H01L 29/66143; H01L 21/2855; H01L 21/2686; H01L 21/324; H01L 29/47; H01L 29/45

(57) ABSTRACT

A method for producing a Schottky diode, including the following steps: oxygenating the surface of a semiconductive layer of monocrystalline diamond, in such a way as to replace hydrogen surface terminations of the semiconductive layer with oxygen surface terminations; and forming, by physical vapour deposition, a first conductive layer of zirconium or indium-tin oxide on the surface of the semiconductive layer.

### BACKGROUND

The present application relates to the forming of electronic components inside and on top of single-crystal diamond substrates. It more specifically aims at the forming of a Schottky diode comprising a Schottky contact between a single-crystal diamond semiconductor layer and a conductive layer

### DISCUSSION OF RELATED ART

It has already been provided in literature to form electronic components, and particularly Schottky diodes, by using doped single-crystal diamond as a semiconductor material. Diamond indeed has physical and electronic properties which make it particularly attractive, particularly for high-power applications.

However, in practice, a major limitation to the use of diamond Schottky diodes is that, to date, known manufacturing methods do not enable to obtain diodes having sufficiently high, stable, and reproducible electric performances for an industrial application.

### SUMMARY

Thus, an object of an embodiment is to provide a method of manufacturing a diamond Schottky diode, this method overcoming all or part of the disadvantages of known methods.

Thus, an embodiment provides a Schottky diode manufacturing method, comprising the steps of: a) oxygenating the surface of a single-crystal diamond semiconductor layer, to replace hydrogen surface terminations of the semiconductor layer with oxygen surface terminations; and b) forming, by physical vapor deposition, a first conductive zirconium or indium tin oxide layer at the surface of the semiconductor layer.

According to an embodiment, at step a), the semiconductor layer is placed in an enclosure containing oxygen at a pressure lower than the atmospheric pressure, and is irradiated with ultraviolet light.

According to an embodiment, the first conductive layer is a zirconium layer and is formed, at step b), by vaporization of a target comprising zirconium by means of an electron beam.

According to an embodiment, at step b), the semiconductor layer and the zirconium target are placed in an enclosure at a pressure lower than the atmospheric pressure.

According to an embodiment, the method further comprises, after step b), a step of annealing the zirconium layer at a temperature in the range from 300 to 500° C.

According to an embodiment, the first conductive layer is an indium tin oxide layer and is formed, at step b), by sputtering of an indium tin oxide target.

According to an embodiment, at step b), the semiconductor layer and the indium tin oxide target are placed in an enclosure containing an argon plasma.

According to an embodiment, the method further comprises, after step b), an anneal of recrystallization of the indium tin oxide layer at a temperature in the range from 100 to 300° C.

According to an embodiment, the method further comprises, after step b), depositing at least one second conductive layer at the surface of the first conductive layer, the conductive layers forming together an electrode of the Schottky diode.

According to an embodiment, the second conductive layer comprises a gold layer.

According to an embodiment, the first conductive layer is made of zirconium and the second conductive layer comprises a platinum layer between the zirconium layer and the gold layer.

According to an embodiment, the semiconductor layer is P-type doped.

According to an embodiment, the semiconductor layer is formed by epitaxy on a single-crystal diamond semiconductor layer of the same conductivity type, but more heavily doped.

According to an embodiment, the method further comprises forming an electrode forming an ohmic contact with the more heavily doped layer.

According to an embodiment, the thickness of the first conductive layer deposited at step b) is in the range from 20 to 30 nm.

### BRIEF DESCRIPTION OF THE DRAWINGS

The foregoing and other features and advantages will be discussed in detail in the following non-limiting description of specific embodiments in connection with the accompanying drawings, among which:

FIGS. 1A to 1D are cross-section views schematically illustrating steps of an embodiment of a method of manufacturing a Schottky diode comprising a Schottky contact between a single-crystal diamond semiconductor layer and a conductive layer;

FIG. 2 is a top view of the structure of FIG. 1D; and

FIGS. 3 and 4 are diagrams illustrating electric operation characteristics of a Schottky diode formed by the method of FIGS. 1A to 1D.

For clarity, the same elements have been designated with the same reference numerals in the various drawings and, further, as usual in the representation of integrated circuits, the various drawings are not to scale.

### DETAILED DESCRIPTION

In the following description, unless otherwise indicated, terms “approximately”, “substantially”, “about”, and “in the order of” mean “to within 10%”.

Up to now, all attempts made by actors in the field of diamond electronic components to obtain a diamond Schottky diode having both a high reverse breakdown voltage, for example, greater than 100 volts, and a high on-state current density, for example, greater than 500 A/cm2 under 7 volts at ambient temperature, have failed.

Further, known manufacturing methods pose other problems which make them unfit for the manufacturing at an industrial scale of diamond Schottky diodes. In particular, known methods raise reproducibility issues, that is, significant differences in electric performances, due to manufacturing differences, can be observed between different diodes formed by a same method. Further, diodes obtained by known methods have temperature stability issues, that is, significant differences in electric performances can be observed when the temperature varies. Further, when the diode temperature exceeds a given temperature, for example, in the order of 250° C., an irreversible degradation of the Schottky junction can be observed. This is particularly disturbing in high-power applications where a significant heating of the diode may occur when the diode conducts.

Studies made by the inventors seem to show that the surface states at the interface between the conductive material of the Schottky junction and the semiconductor diamond might be the cause of all or part of the above-mentioned problems.

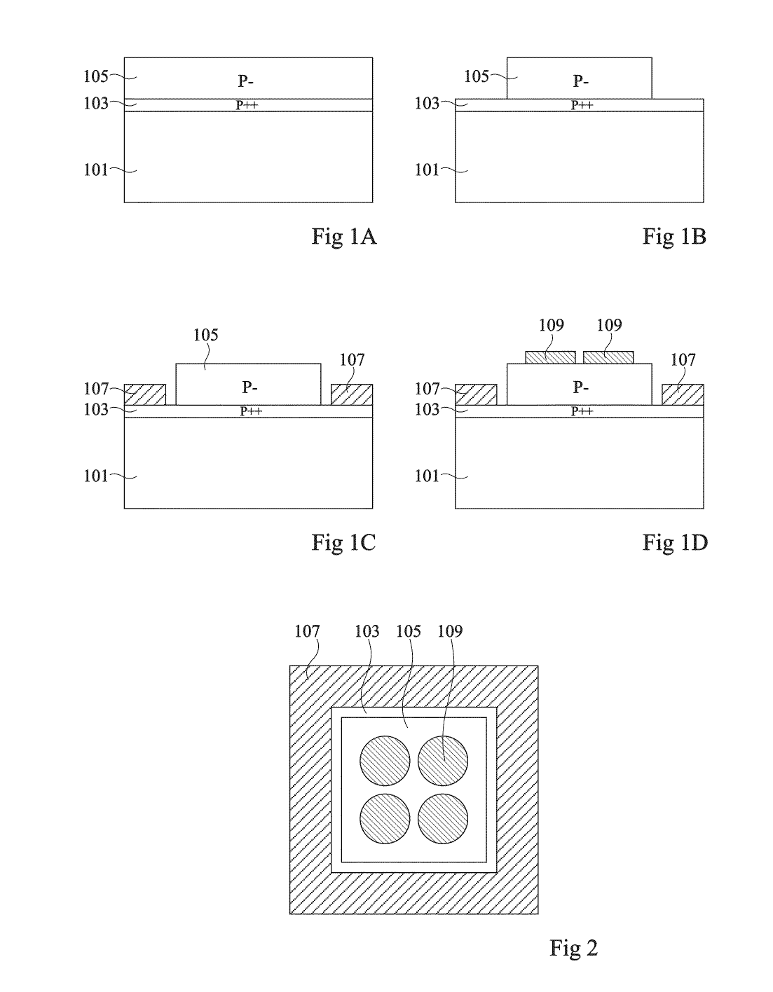

FIGS. 1A to 1D are cross-section views schematically illustrating steps of an embodiment of a method of manufacturing a Schottky diode comprising a Schottky contact between a diamond semiconductor layer and a conductive layer.

FIG. 1A illustrates an initial structure comprising a single-crystal diamond substrate 101 coated with a heavily-doped P-type diamond epitaxial layer 103 (P++). Layer 103 is itself coated with a lightly-doped P-type diamond epitaxial layer 105 (P−). Substrate 101 is for example made of natural cut diamond, or of synthetic diamond obtained by growth at high pressure and high temperature, by chemical vapor deposition, or by any other known technique. The thickness of substrate 101 is for example in the range from 300 to 700 μm, for example, in the order of 500 μm. Epitaxial layers 103 and 105 are for example obtained by steps of microwave plasma chemical vapor deposition or MPCVD. Layers 103 and 105 are for example boron-doped. As an example, layer 103 contains boron at a concentration in the range from 1019 to 1021 atoms/cm3, for example, in the order of 5×1020 atoms/cm3, and layer 105 contains boron at a concentration in the range from 1014 to 1016 atoms/cm3, for example, in the order of 1015 atoms/cm3. As an example, layer 103 has a thickness in the range from 100 to to 300 nm, for example, in the order of 200 nm, and layer 105 has a thickness in the range from 500 nm to 50 μm, for example, in the order of 1,300 nm. To obtain a relatively high breakdown voltage, a layer 105 having a thickness in the range from 3 to 15 μm may be provided. The surface area, in top view, of substrate 101 and of layers 103 and 105 is for example in the order of a few square millimeters. In this example, substrate 101 and layers 103 and 105 have, in top view, the shape of a square with an approximate 3-mm side length.

FIG. 1B illustrates a step of etching a portion of P- layer 105. In this example, a peripheral portion of layer 105, for example, a peripheral strip having a width in the order of 1 mm in top view, is removed by etching to make a portion of the upper surface (in the orientation of the drawings) of layer 103 accessible. The etching is for example an inductively coupled plasma reactive ion etching ICP-RIE. However, any other known technique may be used to etch layer 105. In this example, at the end of the etch step, the remaining portion of layer 105 has, in top view, the shape of a square having an approximately 2-mm side length arranged at the center of layer 103.

FIG. 1C illustrates a step of forming an electrode 107 coating the portion of P++ layer 103 which is not coated with layer 105, this electrode forming an ohmic contact with layer 103. Electrode 107 forms the anode of the Schottky diode, and is electrically connected to the lower surface (in the orientation of the drawings) of layer 105 via P++ layer 103 (it is generally spoken of a pseudo-vertical Schottky diode to designate this type of structure).

As an example, electrode 107 comprises a stack comprising, in the following order from the surface of layer 103, a titanium layer having an approximate 30-nm thickness, a platinum layer having an approximate 50-nm thickness, and a gold layer having an approximate 40-nm thickness. For simplification, the different layers of the stack have not been shown in the drawings. The titanium, platinum, and gold layers may be deposited in a plurality of successive steps, for example, by electron beam physical vapor deposition or EBPVD. After the successive metal depositions, an anneal at a temperature higher than 450° C., for example, at a temperature in the order of 750° C. for approximately 30 minutes, may be provided. In this example, during the anneal, titanium carbide forms at the interface between layer 103 and electrode 107, which enables not only to create an ohmic contact between electrode 107 and diamond layer 103, but also to provide the bonding of electrode 107 to layer 103. Other materials, other thicknesses, and/or other manufacturing methods may however be used to form electrode 107. It should be noted that a mask (not shown in the drawings), for example, made of resin, may be formed prior to the deposition of electrode 107, to delimit the shape, in top view, of electrode 107. In the shown example, a thin space, for example, with a width in the order of a few μm in top view, separates electrode 107 from P− layer 105, so that electrode 107 is not in direct contact with layer 105.

Before depositing, on the upper surface (in the orientation of the drawings) of semiconductor layer 105, a conductive layer forming a Schottky contact with layer 105, a step of oxygenating the upper surface of layer 105 is provided. As an example, after the forming of electrode 107, the structure is placed in a vacuum enclosure, after which oxygen is introduced into the enclosure and the upper surface of layer 105 is irradiated with an ultraviolet radiation. This leads to replacing the hydrogen terminations of the upper surface of diamond layer 105 with oxygen terminations. Such a diamond oxygenation method, known per se, is for example described in T. Teraji et al's article, published in Journal of Applied Physics 105, 126109 (2009). It should be noted that vacuum enclosure here means an enclosure where the pressure is lower than the atmospheric pressure, for example, in the order of 10-5 millibars. When oxygen is present in the enclosure, the pressure in the enclosure is for example in the order of 0.4 millibars. As an example, the time of exposure of the structure to oxygen and to ultraviolet radiation is in the range from 1 hour to 3 hours. The oxygenation step is for example carried out at ambient temperature.

More generally, any other method capable of replacing hydrogen surface terminations of the diamond with oxygen surface terminations may be used, for example, a plasma oxygenation method.

It should be noted that single-crystal diamond has the advantage that its surface terminations, be they hydrogen or oxygen, are very stable once modified. The transfer of the substrate from one enclosure to another during the different method steps thus raises no specific problem.

FIG. 1D illustrates a step of forming a conductive electrode 109 on the upper surface of doped diamond layer (P-) 105, forming a Schottky contact with layer 105. FIG. 2 is a top view of the structure of FIG. 1D.

A mask, not shown in the drawings, for example, made of resin, may be formed prior to the deposition of electrode 109, to define the shape, in top view, of electrode 109. After the opening of the mask at the level of the area of deposition of electrode 109 on layer 105, a step of cleaning the deposition area is preferably provided to remove any resin residue likely to be present on the surface of layer 105. As an example, the cleaning is implemented by capacitively coupled plasma reactive ion etching CCP-RIE. The area of deposition of electrode 109 is for example exposed to the etch plasma for a duration of approximately 30 seconds. Any other know cleaning method may however be used instead of or as a complement to the above-mentioned cleaning method.

In the shown example, electrode 109, or cathode of the Schottky diode comprises four separate adjacent sub-electrodes approximately circular in top view, which actually amounts to forming a structure comprising four common-anode Schottky diodes (electrode 107). Of course, other arrangements of electrode 109 may be provided according to the envisaged use (for example, a single continuous electrode 109 coating the entire surface of layer 105).

According to a first aspect, electrode 109 comprises a thin zirconium layer, deposited at the surface of diamond layer 105 and forming a Schottky contact or rectifying contact with layer 105. The zirconium layer is formed by electron beam physical vapor deposition or EBPVD. For this purpose, the structure is placed in a vacuum enclosure containing a zirconium target, and the target is bombarded with an electron beam. The electron beam tears off or vaporizes zirconium atoms from the target—it is also spoken of a vaporization of the target. The vaporized zirconium atoms then precipitate or adsorb in solid form, covering the surface of the structure with a thin zirconium layer. It should be noted that vacuum chamber here means an enclosure where the pressure is lower than the atmospheric pressure, for example, in the range from 10-6 to 10-8 millibars and preferably in the order of 10-7 millibars, preferably under a non-oxygenated atmosphere. The deposition is for example performed at ambient temperature. The speed of the zirconium deposition on the upper surface of diamond layer 105 is for example in the order of 0.1 nm per second. The thickness of the deposited zirconium layer is for example in the range from 10 to 50 nm, and preferably in the range from 20 to 30 nm.

Electrode 109 may further comprise one or a plurality of other conductive materials coating the surface of the zirconium layer opposite to diamond layer 105. For simplification, the different layers of electrode 109 have not been differentiated in the drawings. As an example, the zirconium layer may be coated with a gold layer especially having the function of avoiding the oxidation of zirconium and of thickening the electrode. As a variation, a platinum barrier layer, for example, having a thickness in the range from 20 to 40 nm, may be deposited between the zirconium layer and the gold layer, the platinum layer especially having the function of avoiding the diffusion of gold in the zirconium, which especially enables the diode to withstand high temperatures with no damage, for example, in the order of 400° C., or even more. As a variation, electrode 109 may comprise a nickel layer, for example having a thickness in the range from 100 to 300 nm, between the platinum layer and the gold layer, this nickel layer especially being used to thicken the electrode.

After the forming of the zirconium layer (before or after the forming of possible upper conductive layers of electrode 109), an anneal may be provided, for example, at a temperature in the range from 300 to 500° C., to further improve the quality of the zirconium/diamond interface forming the Schottky junction of the diode.

According to a second aspect, electrode 109 comprises a thin conductive indium tin oxide layer, generally called ITO in the art, deposited at the surface of diamond layer 105 and forming a Schottky contact or rectifying contact with the layer. The ITO layer is formed by cathode sputtering, for example, under argon. To achieve this, the structure is placed in a chamber containing an ITO target, and the target is bombarded by means of a plasma containing heavy atoms, for example, argon, and preferably containing no oxygen. The plasma tears off or sputters atoms from the ITO target. These atoms then deposit on the surface of the structure, coating it with a thin ITO layer. The ITO deposition is for example performed at ambient temperature. The thickness of the deposited ITO layer is for example in the range from 10 to 50 nm, and preferably in the range from 20 to 30 nm After the deposition, an anneal for recrystallizing the ITO is preferably provided, for example, at a temperature in the range from 100 to 300° C. and preferably at a temperature in the order of 200° C. The duration of the recrystallization anneal is for example in the range from 15 to 60 minutes, for example, approximately 30 minutes. The recrystallization anneal is for example performed under non-modified atmosphere (air).

Electrode 109 may further comprise one or a plurality of other conductive materials coating the surface of the ITO layer opposite to diamond layer 105. For simplification, the different layers of electrode 109 have not been differentiated in the drawings. As an example, the ITO layer may be coated with a protective gold layer having a thickness from 10 to 20 nm or more.

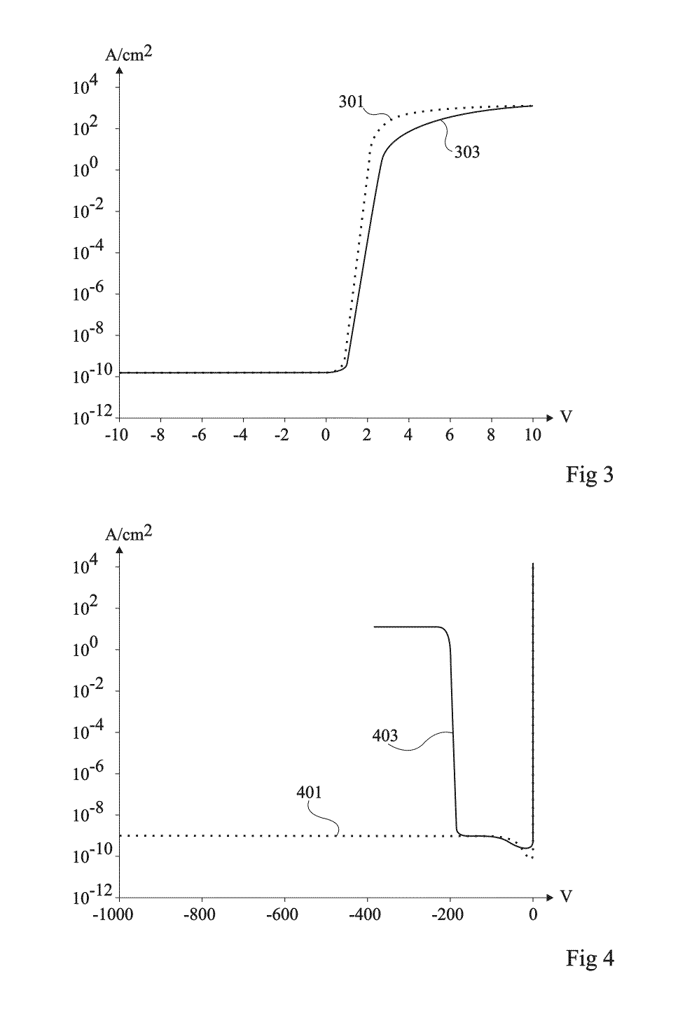

As appears in FIGS. 3 and 4 which will be described in further detail hereafter, an important and advantageous feature of Schottky diodes formed with the method of FIGS. 1A to 1D, be they formed with a zirconium/diamond Schottky junction or with an ITO/diamond Schottky junction, is that they have both a high reverse breakdown voltage and a high on-state current density (that is, a good forward conductivity), which never had been observed before for diamond Schottky diodes.

Such features could be obtained due to the quality of the interface between the conductive layer and the diamond semiconductor layer of the Schottky junction, obtained by combining the use of a step of oxygenating the surface terminations of diamond layer 105, prior to the forming of the conductive layer, and the use of a zirconium deposition by electron gun vaporization or of an ITO deposition by cathode sputtering, to form the conductive layer.

FIG. 3 is a diagram showing the variation of the current density, in A/cm2, flowing through the Schottky diode formed by the method of FIGS. 1A to 1D, according to the voltage, in volts (V), applied between the anode (electrode 107) and the cathode (electrode 109) of the diode, in the vicinity of the threshold voltage (forward turn-on voltage) of the diode. Curve 301, in dotted lines in FIG. 3, corresponds to a zirconium/diamond diode, and curve 303, in full line in FIG. 3, corresponds to an ITO/diamond diode.

FIG. 4 is a diagram showing the variation of the current density, in A/cm2, flowing through the Schottky diode formed by the method of FIGS. 1A to 1D, according to the voltage, in volts (V), applied between the anode and the cathode of the diode, in the vicinity of the reverse breakdown voltage of the diode. Curve 401, in dotted lines in FIG. 4, corresponds to a zirconium/diamond diode, and curve 403, in full line in FIG. 4, corresponds to an ITO/diamond diode.

For a zirconium/diamond diode, the inventors have measured, at ambient temperature (in the order of 27° C.), a current density in the order of 1,000 A/cm2 under 7 V in the conductive mode (curve 301), and a reverse breakdown voltage greater than 1,000 V (curve 401). It should be noted that the measurements which have been made have not enabled to determine the exact value of the breakdown voltage, but have shown that the breakdown voltage is greater than 1,000 V.

For an ITO/diamond diode, the inventors have measured, at ambient temperature, a current density in the order of 640 A/cm2 under 7 V in the conducting mode (curve 303), and a reverse breakdown voltage in the order of 200 V (curve 403).

Further, the inventors have observed that in the blocked mode, leakage currents in the diode are extremely low, typically lower than 10-9 A/cm2 until the voltage comes close to the breakdown voltage for an ITO/diamond diode (curves 303 and 403), and lower than 10-9 A/cm2 until the voltage reaches at least 1,000 V for a zirconium/diamond diode (curves 301 and 401).

The inventors have further determined that for a zirconium/diamond diode where electrode 109 further comprises a platinum layer coating the zirconium layer and a gold layer coating the platinum layer, the barrier height, in electron volts (eV), between diamond layer 105 and the zirconium layer, is in the order of:

1.97 eV, which translates as a threshold voltage of approximately 2.35 V for a 1-mA current and a 12.74-A/cm2 current density, if the deposition of the zirconium layer is not followed by an anneal;

1.4 eV, which translates as a threshold voltage of approximately 1.95 V for a 1-mA current and a 12.74-A/cm2 current density, if the deposition of the zirconium layer is followed by an anneal at a temperature in the order of 350° C.; and

1 eV, which translates as a threshold voltage of approximately 1.1 V for a 1-mA current and a 12.74 A/cm2 current density, if the deposition of the zirconium layer is followed by an anneal at a temperature in the order of 450° C.

Thus, the provision of an anneal after the deposition of the zirconium layer enables to lower the barrier height of the Schottky junction, and thus to decrease on-state losses. Further, such an anneal enables to improve the thermal stability of the diode.

Another advantage of the method of FIGS. 1A to 1D is that the electric characteristics of the obtained Schottky diodes are perfectly reproducible from one diode to another.

Another advantage of the method of FIGS. 1A to 1D is that it enables to obtain Schottky diodes having temperature-stable performances, and withstanding, with no damage, high temperatures, typically in the order of 400° C. or more.

As a result of the foregoing, the method of FIGS. 1A to 1D is compatible with the forming of diamond Schottky diodes for a use at an industrial scale.

Specific embodiments have been described. Various alterations and modifications will occur to those skilled in the art. In particular, although the provided method has been described to in relation with an embodiment of a Schottky diode with a pseudo-vertical structure, the described embodiments are not limited to this specific case. It will be within the abilities of those skilled in the art to use the provided method to form Schottky diodes having other structures, for example, a really vertical structure, where anode electrode 107 is arranged on the side of layer 105 opposite to electrode 109.

Further, although the provided method has been described in the case where the semiconductor diamond layer of the Schottky junction is of type P, it will be within the abilities of those skilled in the art to adapt the provided method to the forming of a diamond Schottky diode where the semiconductor diamond layer of the Schottky junction is of type N

What is claimed is:

1. A method of manufacturing a Schottky diode, comprising the steps of:
a) oxygenating the surface of a single-crystal diamond semiconductor layer, to replace hydrogen surface terminations of the semiconductor layer with oxygen surface terminations: and
b) forming, by physical vapor deposition, a first indium tin oxide conductive layer at the surface of the semiconductor layer.

2. The method of claim 1, wherein at step a), the semiconductor layer is placed in an enclosure containing oxygen at a pressure lower than the atmospheric pressure, and is irradiated with ultraviolet light.

3. The method of claim 1, wherein the first conductive layer is formed, at step b), by sputtering of an indium tin oxide target.

4. The method of claim 3, wherein, at step b), the semiconductor layer and the indium tin oxide target are placed in an enclosure containing an argon plasma.

5. The method of claim 3, further comprising, after step b), an anneal of recrystallization of the indium tin oxide layer at a temperature in the range from 100 to 300° C.

6. The method of claim 1, further comprising, after step b), depositing at least a second conductive layer at the surface of the first conductive layer, said conductive layers forming together an electrode of the Schottky diode.

7. The method of claim 6, wherein said at least one second conductive layer comprises a gold layer.

8. The method of claim 1, wherein the semiconductor layer P-type doped.

9. The method of claim 1, wherein the semiconductor layer is formed by epitaxy on a single-crystal diamond semiconductor layer of the same conductivity type, but more heavily doped.

10. The method of claim 9, further comprising forming an electrode forming an ohmic contact with said more heavily doped layer.

11. The method of claim 1, wherein the thickness of the first conductive layer deposited at step b) ranges from 20 to 30 nm.
